(19) United States
(12) Patent Application Publication
(10) Pub. No.: US 2022/0130836 A1
(43) Pub. Date: Apr. 28, 2022

(54) SEMICONDUCTOR STRUCTURE FORMATION METHOD AND SEMICONDUCTOR STRUCTURE

(71) Applicant: CHANGXIN MEMORY TECHNOLOGIES, INC, Hefei City (CN)

(72) Inventors: Longyang CHEN, Hefei City (CN); Hongfa Wu, Hefei City (CN); Gongyi Wu, Hefei City (CN)

(21) Appl. No.: 17/456,085

(22) Filed: Nov. 22, 2021

Related U.S. Application Data
(63) Continuation of application No. PCT/CN2021/106070, filed on Jul. 13, 2021.

(30) Foreign Application Priority Data
Oct. 28, 2020 (CN) 202011176293.0

(51) Int. Cl. H01L 27/108

(52) U.S. Cl. CPC H01L 27/10852; H01L 27/10829; H01L 27/10814

(57) ABSTRACT

Embodiments of the present application provide a semiconductor structure formation method and a semiconductor structure. The semiconductor structure formation method includes: providing a substrate, the substrate including a contact region and a virtual region arranged adjacent to each other, a bitline structure and a dielectric layer arranged discretely being formed on the substrate, an extension direction of the dielectric layer intersecting with that of the bitline structure, and the bitline structure and the dielectric layer defining discrete capacitor contact openings; forming a sacrificial layer filling the capacitor contact opening; removing, in the contact region, the sacrificial layer to form a second opening; forming a bottom conductive layer filling the second opening; removing, in the virtual region, some height of the sacrificial layer to form a first opening; forming an insulation layer filling the first opening; and forming a capacitor contact structure located in the second opening.

### CROSS-REFERENCE TO RELATED APPLICATIONS

This application is a continuation application of International Patent Application No. PCT/CN2021/106070, filed on Jul. 13, 2021, which claims priority to Chinese Patent Application No. 202011176293.0, filed with the Chinese Patent Office on Oct. 28, 2020 and entitled “SEMICONDUCTOR STRUCTURE FORMATION METHOD AND SEMICONDUCTOR STRUCTURE” International Patent Application No. PCT/CN2021/106070 and Chinese Patent Application No. 202011176293.0 are incorporated herein by reference in their entireties.

### TECHNICAL FIELD

The present application relates to the field of semiconductors, and in particular, to a semiconductor structure formation method and a semiconductor structure.

### BACKGROUND

The development of a Dynamic Random Access Memory (DRAM) is characterized by a high speed, high integration density and low power consumption.

With the miniaturization of a semiconductor structure in size, especially during the manufacturing of the DRAM with a critical dimension less than 20 nm, an etch load effect of an array region and a peripheral region of the DRAM becomes greater and greater. In order to ensure the integrity and effectiveness of a circuit structure in the array region of the DRAM, a virtual structure is generally required to be designed in the array region.

During the manufacturing of the DRAM, a virtual capacitor contact structure and a virtual bitline structure are the most common virtual structures. However, the applicant finds that, due to a requirement of a manufacturing process, a wet cleaning process is needed multiple times in the manufacturing process of a capacitor contact structure, which leads to damages to part of the virtual capacitor contact structure, thereby forming a deep void. With the miniaturization of the critical dimension, conductors of a capacitor contact pad are more and more densely arranged. During the formation of the conductors of the capacitor contact pad, the void is easy to be filled with metal materials, resulting in short circuit of the formed conductors of the capacitor contact pad.

### SUMMARY

Embodiments of the present application provide a semiconductor structure formation method and a semiconductor structure.

In order to solve the above technical problem, the embodiments of the present application provide a semiconductor structure formation method, including: providing a substrate, the substrate including a contact region and a virtual region arranged adjacent to each other, a bitline structure and a dielectric layer arranged discretely being formed on the substrate, an extension direction of the dielectric layer intersecting with that of the bitline structure, and the bitline structure and the dielectric layer defining discrete capacitor contact openings; forming a sacrificial layer filling the capacitor contact opening; removing, in the contact region, the sacrificial layer to form a second opening; forming a bottom conductive layer filling the second opening; removing, in the virtual region, some height of the sacrificial layer to form a first opening; forming an insulation layer filling the first opening; and forming a capacitor contact structure located in the second opening.

The embodiments of the present application further provide a semiconductor structure, including: a substrate including a contact region and a virtual region arranged adjacent to each other; a bitline structure and a dielectric layer, an extension direction of the dielectric layer intersecting with that of the bitline structure, and the bitline structure and the dielectric layer defining discrete capacitor contact openings; a sacrificial layer filling the capacitor contact opening in the virtual region, a height of a top surface of the sacrificial layer being less than that of a top surface of the bitline structure; an insulation layer filling the capacitor contact opening in the virtual region and located on the top surface of the sacrificial layer, a height of a top surface of the insulation layer being flush with that of the top surface of the bitline structure; and a capacitor contact structure filling the capacitor contact opening in the contact region.

### BRIEF DESCRIPTION OF DRAWINGS

One or more embodiments are exemplarily described by using figures that are corresponding thereto in the accompanying drawings. Unless otherwise particularly stated, the figures in the accompanying drawings do not constitute a scale limitation.

FIG. 1 is a schematic top view of a semiconductor structure according to a first embodiment of the present application;

FIG. 2, FIG. 7, FIG. 10, FIG. 13, FIG. 20 and FIG. 22 are schematic sectional views corresponding to steps along direction A1 in a semiconductor structure formation method according to the first embodiment of the present application;

FIG. 3, FIG. 5, FIG. 8, FIG. 11, FIG. 14, FIG. 16 and FIG. 18 are schematic sectional views corresponding to steps along direction A2 in the semiconductor structure formation method according to the first embodiment of the present application; and

FIG. 4, FIG. 6, FIG. 9, FIG. 12, FIG. 15, FIG. 17, FIG. 19, FIG. 21 and FIG. 23 are schematic sectional views corresponding to steps along direction A3 in the semiconductor structure formation method according to the first embodiment of the present application.

### DESCRIPTION OF EMBODIMENTS

Currently, due to a requirement of a manufacturing process, a wet cleaning process is needed multiple times in the manufacturing process of a capacitor contact structure. The wet cleaning process has an etch load effect, and an etch rate may decrease correspondingly for a densely etched region, which leads to overetching of other structures during the formation of a capacitor contact opening, for example, overetching of a virtual capacitor contact structure, resulting in a deep void in the virtual capacitor contact structure. The void is filled with some metal materials during subsequent formation of conductors of a capacitor contact pad. With the miniaturization of a critical dimension, the conductors of the capacitor contact pad are arranged more and more densely, and some metal materials of adjacent conductors of the capacitor contact pad may fill a same void, resulting in short circuit of the conductors of the capacitor contact pad formed.

In order to solve the above problem, a first embodiment of the present application provides a semiconductor structure formation method, including: providing a substrate, the substrate including a contact region and a virtual region arranged adjacent to each other, a bitline structure and a dielectric layer arranged discretely being formed on the substrate, an extension direction of the dielectric layer intersecting with that of the bitline structure, and the bitline structure and the dielectric layer defining discrete capacitor contact openings; forming a sacrificial layer filling the capacitor contact opening; removing, in the contact region, the sacrificial layer to form a second opening; forming a bottom conductive layer filling the second opening; removing, in the virtual region, some height of the sacrificial layer to form a first opening; forming an insulation layer filling the first opening; and forming a capacitor contact structure located in the second opening.

Compared with the related art, in the manufacturing process of forming the capacitor contact structure, some height of a virtual capacitor contact structure and some height of a virtual bitline structure are etched to form the first opening, and the insulation layer filling the first opening is formed, which prevents the problem of short circuit of conductors in a subsequently-formed capacitor contact pad caused by a deep void formed due to damages to part of the virtual capacitor contact structure during the formation of the capacitor contact structure.

In order to make the objectives, technical solutions and advantages of the embodiments of the present application clearer, various embodiments of the present application will be described below in details with reference to the drawings. However, those of ordinary skill in the art may understand that, in the embodiments of the present application, numerous technical details are set forth in order to enable a reader to better understand the present application. However, the technical solutions claimed in the present application can be implemented without these technical details and various changes and modifications based on the embodiments below. The embodiments below are divided for the convenience of description, and should not constitute any limitation on specific implementations of the present application. The embodiments may be combined with each other and mutually referred to without contradiction.

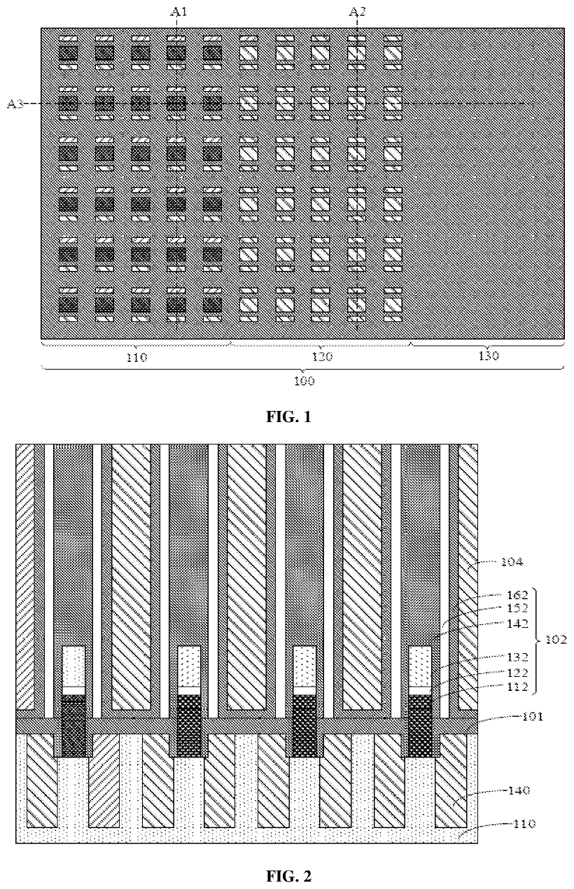

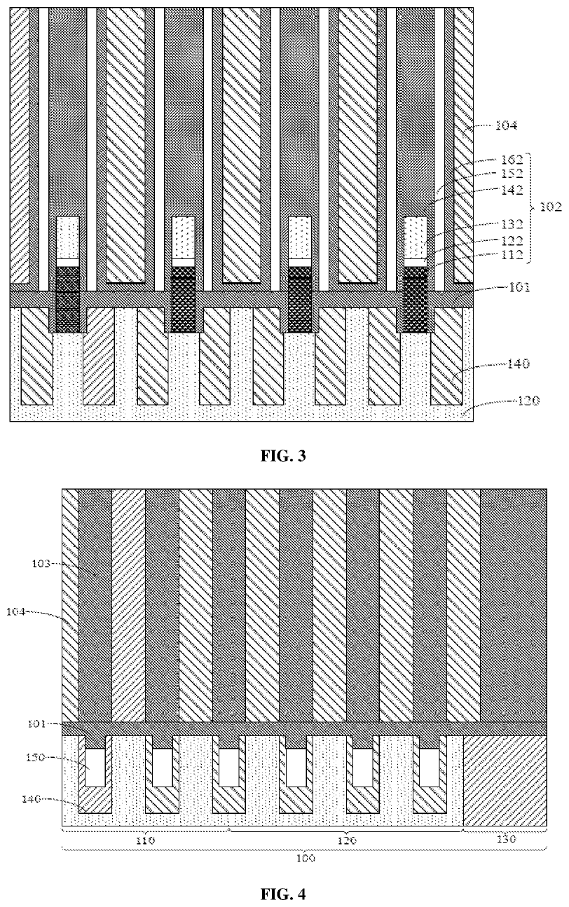

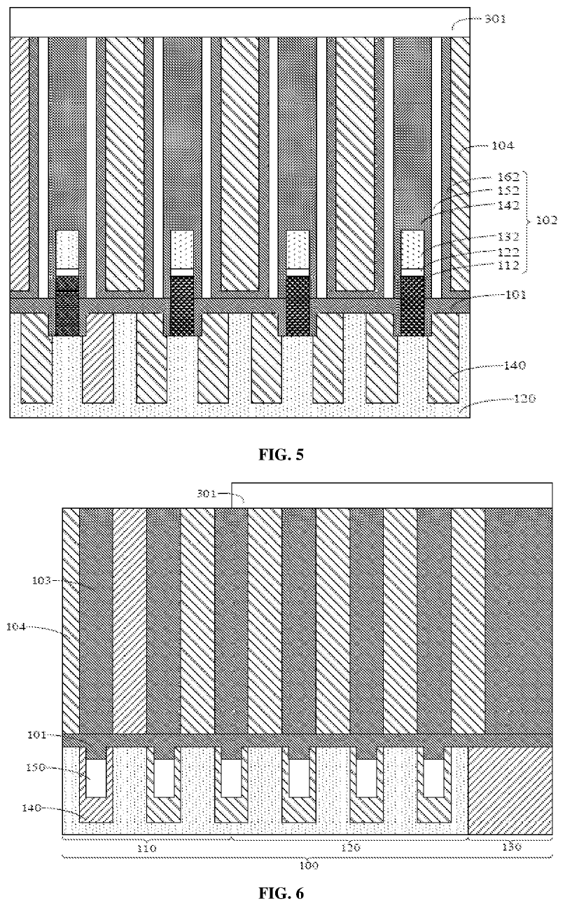

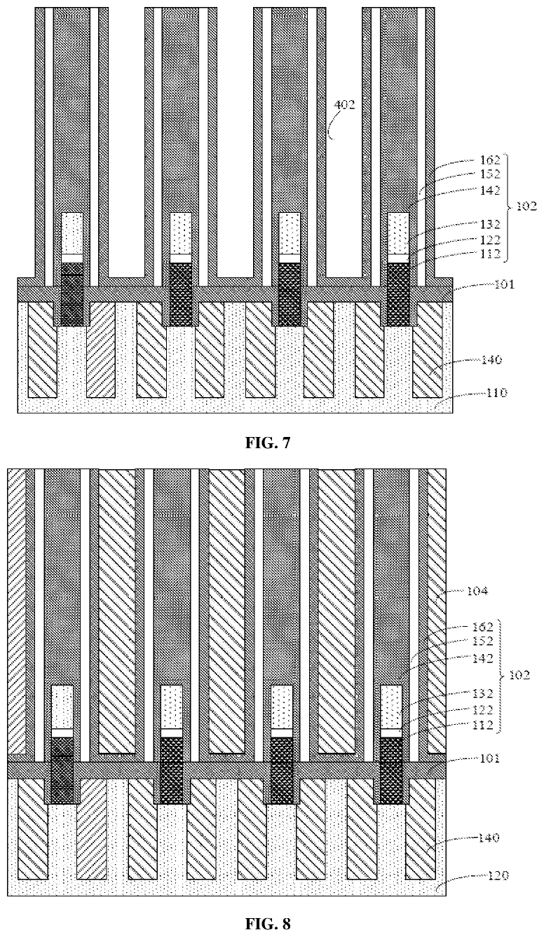

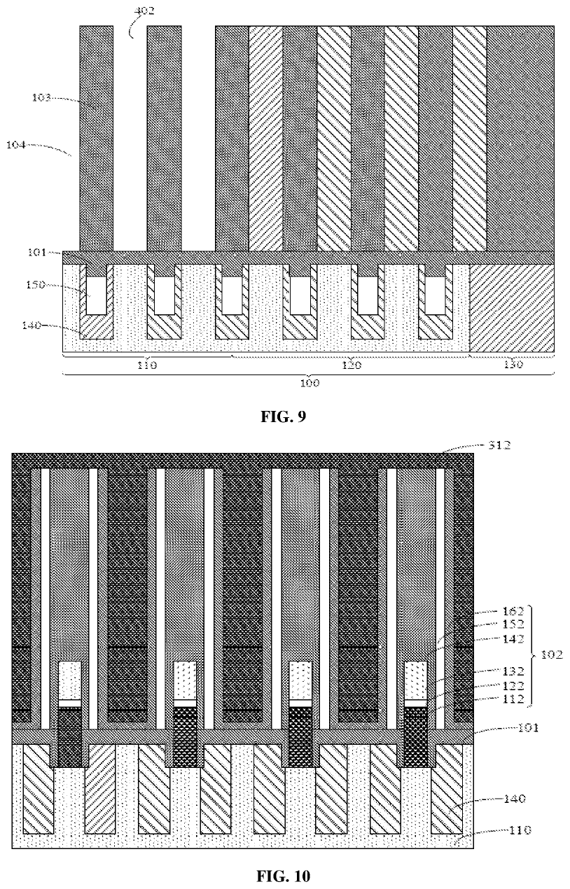

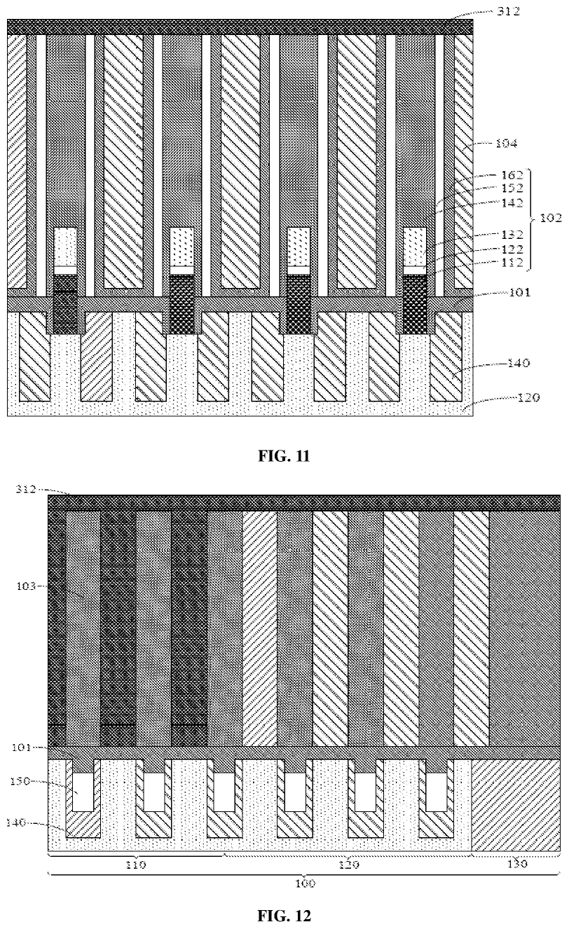

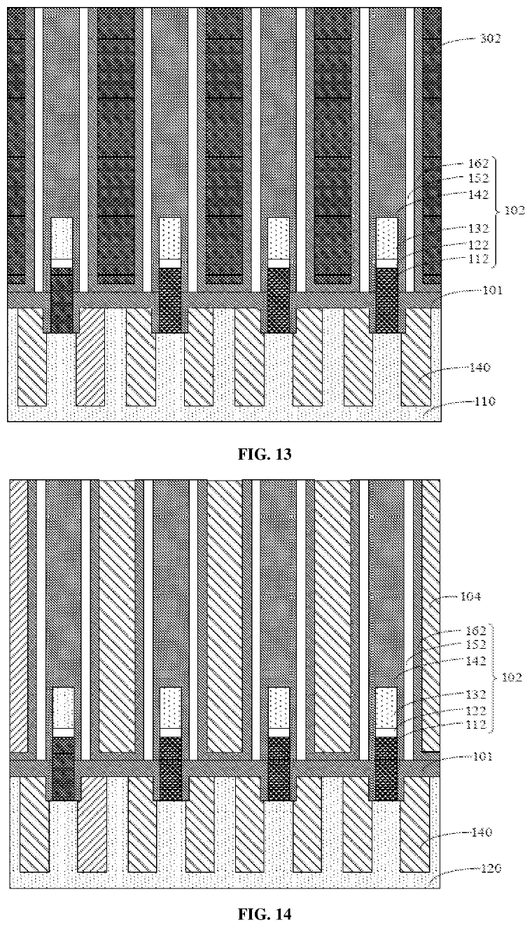

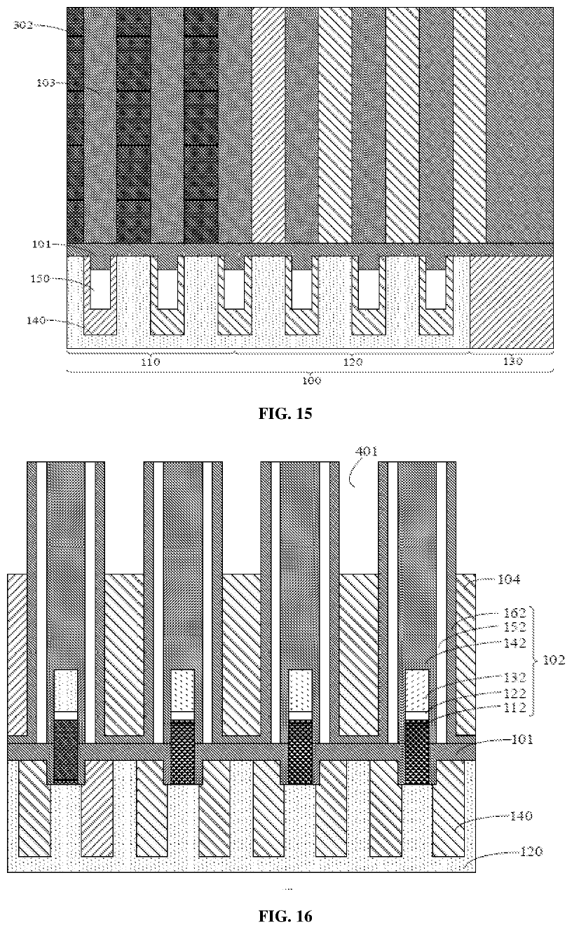

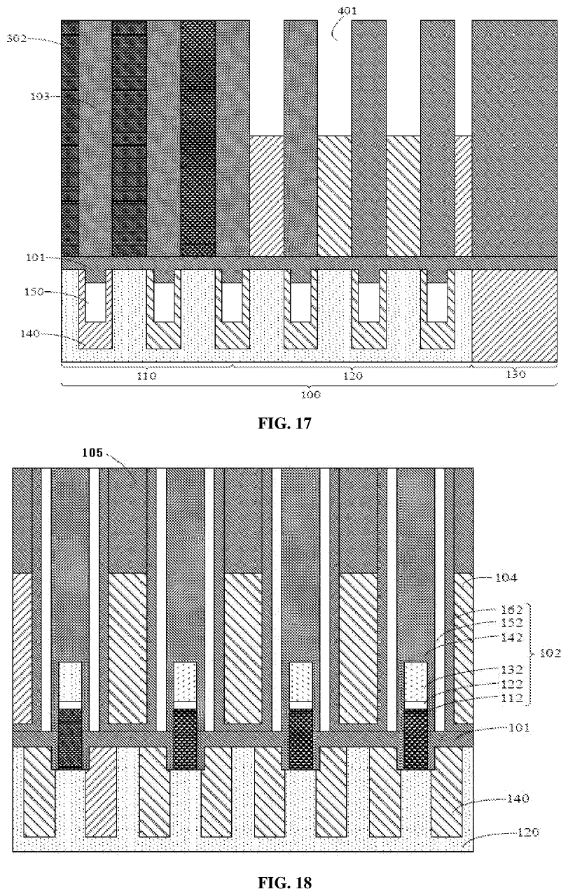

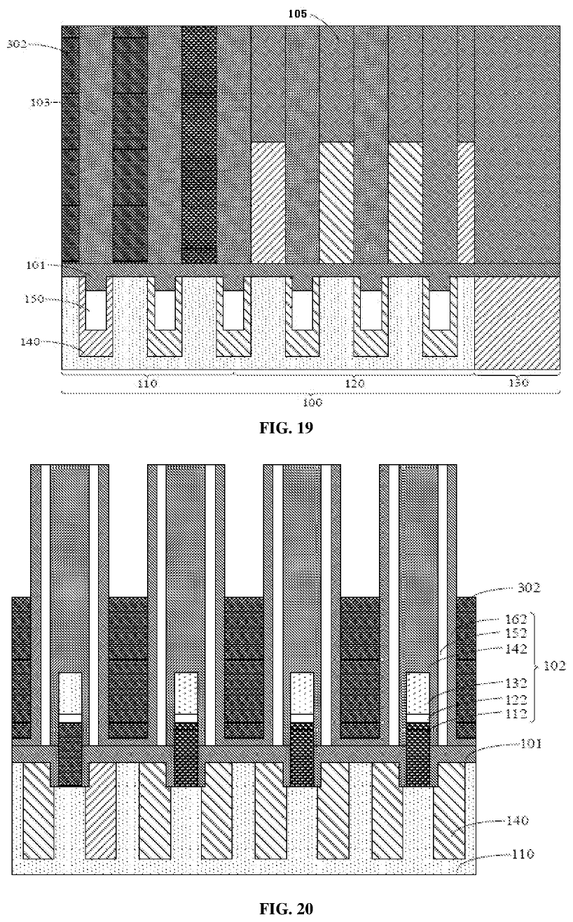

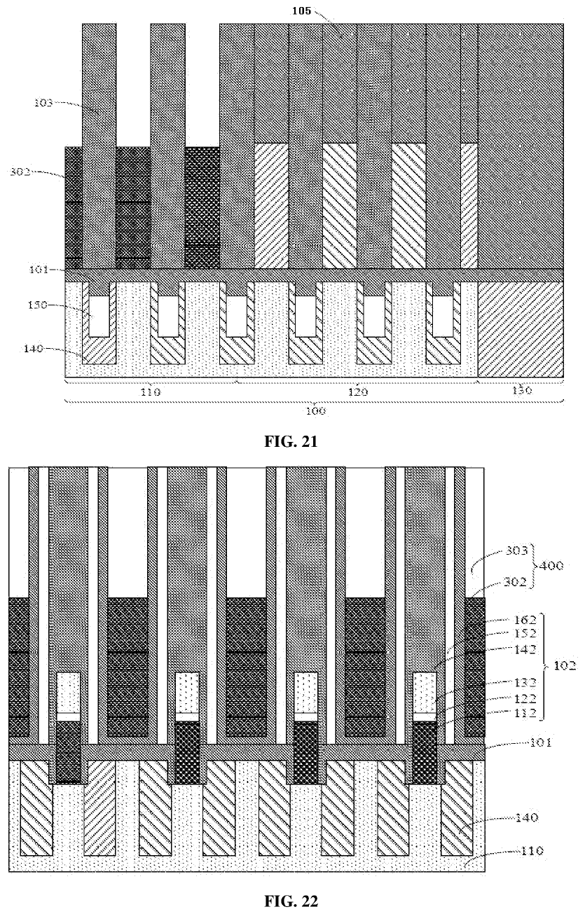

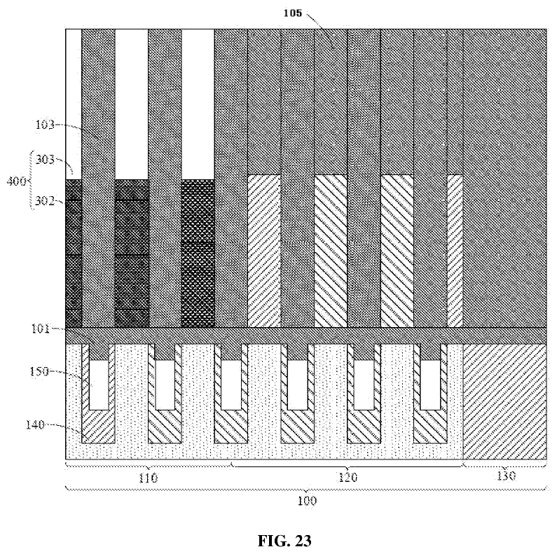

FIG. 1 is a schematic top view of a semiconductor structure according to a first embodiment of the present application; FIG. 2, FIG. 7, FIG. 10, FIG. 13, FIG. 20 and FIG. 22 are schematic sectional views corresponding to steps along direction A1 in a semiconductor structure formation method according to the first embodiment of the present application; FIG. 3, FIG. 5, FIG. 8, FIG. 11, FIG. 14, FIG. 16 and FIG. 18 are schematic sectional views corresponding to steps along direction A2 in the semiconductor structure formation method according to the first embodiment of the present application; and FIG. 4, FIG. 6, FIG. 9, FIG. 12, FIG. 15, FIG. 17, FIG. 19, FIG. 21 and FIG. 23 are schematic sectional views corresponding to steps along direction A3 in the semiconductor structure formation method according to the first embodiment of the present application.

Referring to FIG. 1, a substrate 100 is provided. The substrate 100 includes a contact region 110 and a virtual region 120 arranged adjacent to each other.

The substrate 100 includes an array region and a peripheral region 130. The array region is divided into the contact region 110 and the virtual region 120. The contact region 110 is configured to form a capacitor contact structure configured to realize an electrical connection between a memory capacitor and a transistor. The virtual region 120 is configured to form a virtual capacitor contact structure configured to ensure integrity and effectiveness of a circuit structure of an array region of a DRAM during the manufacturing of the DRAM with a critical dimension less than 20 nm.

In FIG. 1, the direction A3 is an extension direction of a bitline structure, and the direction A1 and the direction A2 are extension directions of a dielectric layer. This embodiment is introduced with an example in which the bitline structure and the dielectric layer extend perpendicularly to each other. In other embodiments, the extension directions of the bitline structure and the dielectric layer intersect with one another to define capacitor contact openings. The capacitor contact openings defined by the dielectric layer and the bitline structure are shown by larger blocks in FIG. 1. The capacitor contact opening in the contact region 110 and the capacitor contact opening in the virtual region 120 are filled differently only to reflect the capacitor contact openings located in different regions, which does not limit materials and structures of the capacitor contact openings.

In FIG. 1, small boxes located on two sides of the capacitor contact opening are isolation layers on a sidewall of the bitline structure. The sidewall of the bitline structure has a structure of a plurality of isolation layers, so as to reduce parasitic capacitance between the bitline structure and a capacitor contact structure formed by filling the capacitor contact opening. It is to be noted that this embodiment is introduced with an example in which the plurality of isolation layers are provided on the sidewall of the bitline structure. The example in which the plurality of isolation layers are provided on the sidewall of the bitline structure is only a preferred implementation and does not constitute a limitation on this embodiment. In other embodiments, the isolation layer on the sidewall of the bitline structure may be of a monolayer structure.

Compared with the related art, the insulation layer filling the first opening in the virtual region, that is, the insulation layer located at a top of a virtual capacitor contact structure defined by a virtual bitline structure and the dielectric layer, prevents the problem of short circuit of conductors in a subsequently-formed capacitor contact pad caused by a deep void formed due to damages to part of the virtual capacitor contact structure during the formation of the capacitor contact structure.

The semiconductor structure formation method according to this embodiment is introduced below with reference to the schematic diagrams of sectional structures taken along the directions A1, A2 and A3 respectively.

Referring to FIG. 2 to FIG. 4, a substrate 100 is provided. The substrate 100 includes a contact region 110 and a virtual region 120 arranged adjacent to each other, a bitline structure 102 and a dielectric layer 103 arranged discretely are formed on the substrate 100, an extension direction of the dielectric layer 103 intersects with that of the bitline structure 102, the bitline structure 102 and the dielectric layer 103 define discrete capacitor contact openings (not shown), and a sacrificial layer 104 filling the capacitor contact opening (not shown) is formed.

The substrate 100 includes a shallow trench isolation structure 140, an insulating layer 101, and a wordline structure 150. The shallow trench isolation structure 140 is configured to isolate adjacent active regions (not shown). The wordline structure 150 is of a buried structure, is formed inside the substrate 100, acts as a gate of the transistor, and is configured to connect the bitline structure 102. It is to be noted that the substrate 100 further includes other semiconductor structures in addition to the shallow trench isolation structure 140 and the wordline structure 150. Since the other semiconductor structures do not involve the core technology of the present application, they are not described in detail herein. Those skilled in the art may understand that the substrate 100 further includes other semiconductor structures in addition to the shallow trench isolation structure 140 and the wordline structure 150, for the normal operation of the semiconductor structure.

The substrate 100 may be made of sapphire, silicon, silicon carbide, gallium arsenide, aluminum nitride, zinc oxide or the like. In this embodiment, the substrate 100 is made of a silicon material. It is clear to those skilled in the art that the substrate 100 being made of the silicon material in this embodiment is intended to facilitate those skilled in the art to understand the subsequent formation method, which does not constitute a limitation. During an actual application, a suitable substrate material may be selected as needed.

The bitline structure 102 includes a bitline contact layer 112, a conductive contact layer 122, a metal layer 132 and a top dielectric layer 142 sequentially stacked.

The bitline contact layer 112 is made of silicon germanium or polysilicon, and is configured for an electrical connection with the wordline structure 150. The conductive contact layer 122 is made of titanium nitride, and is configured for an electrical connection between the bitline contact layer 112 formed by a conductive semiconductor material and the metal layer 132 formed by a conductive metal material to reduce resistance of an electrical connection path between the bitline structure 102 and the wordline structure 150. The metal layer 132 may be made of one or more conductive materials, such as doped polysilicon, titanium, titanium nitride, tungsten and a tungsten compound, and is configured for signal transmission of the bitline structure 102. The top dielectric layer 142 is made of silicon nitride, silicon dioxide, or silicon oxynitride. In this embodiment, the top dielectric layer 142 is made of silicon nitride and is configured to prevent short circuit between the metal layer 132 in the bitline structure 102 and other conductive structures in the DRAM.

In this embodiment, the top dielectric layer 142 further covers sidewalls of the bitline contact layer 112, the conductive contact layer 122 and the metal layer 132 and acts as a first isolation layer of the bitline structure 102. A second isolation layer 152 is further formed on a sidewall of the first isolation layer. A third isolation layer 162 is further formed on a sidewall of the second isolation layer 152. In this embodiment, a structure of a plurality of isolation layers is formed on a sidewall of the bitline structure 102, so as to reduce parasitic capacitance between the bitline structure 102 and a capacitor contact structure formed by filling the capacitor contact opening.

The second isolation layer 152 is made of silicon nitride, silicon dioxide, or silicon oxynitride. In this embodiment, the second isolation layer 152 is made of silicon dioxide. The third isolation layer 162 is made of silicon nitride, silicon dioxide, or silicon oxynitride. In this embodiment, the third isolation layer 162 is made of silicon nitride. In other embodiments, the second isolation layer may also be an air isolation layer. The parasitic capacitance between the bitline structure 102 and the capacitor contact structure formed by filling the capacitor contact opening can be further reduced by air isolation.

The dielectric layer 103 is made of an insulation material. The dielectric layer 103 is made of silicon nitride, silicon dioxide, or silicon oxynitride. In this embodiment, the dielectric layer 103 is made of a same material as the top dielectric layer 142.

In this embodiment, the sacrificial layer 104 is made of silicon oxide formed by Spin-On Deposition (SOD). The sacrificial layer 104 formed by SOD has better adhesion and gap filling capability, which ensures that the formed sacrificial layer 104 can completely fill the capacitor contact opening defined by the dielectric layer 103 and the bitline structure 102.

The step of forming a sacrificial layer 104 filling the capacitor contact opening includes the following steps: forming a sacrificial film (not shown) filling the capacitor contact opening and covering the bitline structure 102 and the dielectric layer 103; and removing the sacrificial film (not shown) higher than a top surface of the bitline structure 102 to form the sacrificial layer 104.

Referring to FIG. 5 to FIG. 9, in the contact region 110, the sacrificial layer 104 is removed to form a second opening 402.

Referring to FIG. 5 and FIG. 6, in the virtual region 120, a first mask layer 301 located on top surfaces of the bitline structure 102, the dielectric layer 103 and the sacrificial layer 104 is formed.

The step of forming a first mask layer 301 includes the following steps: forming a first mask (not shown) located on top surfaces of the bitline structure 102, the dielectric layer 103 and the sacrificial layer 104 in the contact region 110, the virtual region 120 and the peripheral region 130, forming a photoresist on a top surface of the first mask (not shown) in the virtual region 120 and the peripheral region 130, and patterning the first mask (not shown) based on the photoresist to form the first mask layer 301.

Referring to FIG. 7 to FIG. 9, the sacrificial layer 104 in the contact region 110 is removed based on the first mask layer 301 to form the second opening 402. The first mask layer 301 is removed after the second opening 402 is formed.

In this embodiment, the sacrificial layer 104 in the contact region 110 is removed by wet cleaning. According to the wet cleaning, a suitable etch material can be selected to enable the wet cleaning to have a certain etch selectivity ratio for the sacrificial layer 104 and the dielectric layer 103, so as to prevent damages to the formed semiconductor structure caused by the etching of the dielectric layer 103 during the etching of the sacrificial layer 104. In other embodiments, the sacrificial layer in the contact region may also be removed by ion bombardment by means of dry cleaning.

In addition, in other embodiments, the sacrificial layer is made of a carbon-containing material, and the sacrificial layer may be removed by ashing in a subsequent process of removing the sacrificial layer to form a second opening. Ashing gas reacts with the carbon-containing material to produce carbon dioxide gas, so as to convert the sacrificial layer into gaseous carbon dioxide, thereby removing the sacrificial layer, which prevents collapse caused by a larger impact formed on the dielectric layer on the sidewall during the forming of the second opening.

Referring to FIG. 10 to FIG. 15, a bottom conductive layer 302 filling the second opening 402 is formed.

The step of forming a bottom conductive layer 302 includes the following steps.

Referring to FIG. 10 to FIG. 12, a conductive film 312 filling the second opening 402 and covering the contact region 110 is formed.

In this embodiment, the conductive film 312 is made of polysilicon formed by Spin-On Deposition (SOD). The conductive film 312 formed by SOD has better adhesion and gap filling capability, which ensures that the conductive film 312 can completely fill the second opening 402.

Referring to FIG. 13 to FIG. 15, the conductive film 312 higher than a top surface of the bitline structure 102 is removed to form the bottom conductive layer 302 configured to fill the second opening 402.

A top of the conductive film 312 is polished by chemical mechanical polishing until the top surface of the bitline structure 102 is exposed, and the bottom conductive layer 302 filling the second opening 402 is formed. Chemical mechanical polishing has a higher removal rate compared with an etch process, which helps reduce a process cycle.

Referring to FIG. 16 and FIG. 17, in the virtual region 120, some height of the sacrificial layer 104 is removed to form a first opening 401.

In the contact region 110, a second mask layer (not shown) located on top surfaces of the bitline structure 102, the dielectric layer 103 and the bottom conductive layer 302 is formed.

The step of forming a second mask layer (not shown) includes the following steps: forming a second mask (not shown) located on top surfaces of the bitline structure 102, the dielectric layer 103, the sacrificial layer 104 and the bottom conductive layer 302 in the contact region 110, the virtual region 120 and the peripheral region 130, forming a photoresist on a top surface of the second mask (not shown) in the contact region 110, and patterning the second mask (not shown) based on the photoresist to form the second mask layer (not shown).

Some height of the sacrificial layer 104 in the virtual region 120 is removed based on the second mask layer (not shown) to form the first opening 401. The second mask layer (not shown) is removed after the first opening 401 is formed.

In this embodiment, some height of the sacrificial layer 104 in the virtual region 120 is removed by wet cleaning. According to the wet cleaning, a suitable etch material can be selected to enable the wet cleaning to have a certain etch selectivity ratio for the sacrificial layer 104 and the dielectric layer 103, so as to prevent damages to the formed semiconductor structure caused by the etching of the dielectric layer 103 during the etching of the sacrificial layer 104. In other embodiments, some height of the sacrificial layer in the virtual region may also be removed by ion bombardment by means of dry cleaning.

In addition, in other embodiments, the sacrificial layer is made of a carbon-containing material, and the sacrificial layer may be removed by ashing in a subsequent process of removing the sacrificial layer to form a first opening. Ashing gas reacts with the carbon-containing material to produce carbon dioxide gas, so as to convert the sacrificial layer into gaseous carbon dioxide, thereby removing the sacrificial layer, which prevents collapse caused by a larger impact formed on the dielectric layer on the sidewall during the forming of the first opening.

In this embodiment, in a direction perpendicular to the substrate 100, a distance between the metal layer 132 located in the bitline structure 102 and a bottom surface of the first opening 401 formed is 20 nm to 90 nm. If the distance between the metal layer 132 located in the bitline structure 102 and the bottom surface of the first opening 401 formed is less than 20 nm, it indicates that in the etched bitline structure 102, the top dielectric layer 142 is thicker and the remaining top dielectric layer 142 is thinner, so that a distance between the metal layer 132 of the bitline structure 102 and other conductive structures in the DRAM decreases, and the parasitic capacitance between the metal layer 132 and other conductive structures in the DRAM increases. If the distance between the metal layer 132 located in the bitline structure 102 and the bottom surface of the first opening 401 formed is greater than 90 nm, it indicates that the top dielectric layer 142 in the etched bitline structure 102 is thinner, which cannot prevent the problem of short circuit of conductors in a subsequently-formed capacitor contact pad caused by a deep void formed due to damages to part of the virtual capacitor contact structure during the formation of the capacitor contact structure.

Referring to FIG. 18 and FIG. 19, an insulation layer 105 filling the first opening 401 is formed.

The step of forming an insulation layer 105 filling the first opening 401 includes the following steps.

An insulation film (not shown) filling the first opening 401 and covering the contact region 110 is formed.

The insulation film (not shown) is formed by atomic layer deposition or chemical vapor deposition. In this embodiment, the insulation film (not shown) is formed by atomic layer deposition. The insulation film (not shown) formed by atomic layer deposition has good coverage. In other embodiments, for example, the insulation film may be formed by chemical vapor deposition at 500° C. or 600° C. It is to be noted that, the above examples of specific temperature parameters for chemical vapor deposition are intended only to facilitate the understanding of those skilled in the art, which does not constitute a limitation on the solution. In practical applications, parameters within the above range should all fall within the protection scope of the present application.

The insulation film (not shown) is made of silicon nitride, silicon dioxide, or silicon oxynitride. In this embodiment, the insulation film (not shown) is made of silicon nitride.

The insulation film (not shown) is etched until top surfaces of the bitline structure 102 and the dielectric layer 103 are exposed in the contact region 110, so as to form the insulation layer 105.

A top of the insulation film (not shown) is polished by chemical mechanical polishing to form the insulation layer 105 with a relatively-flat top surface. Chemical mechanical polishing has a higher removal rate compared with an etch process, which helps reduce a process cycle.

Referring to FIG. 20 to FIG. 23, a capacitor contact structure 400 located in the second opening 402 is formed.

The step of forming a capacitor contact structure 400 includes the following steps.

Referring to FIG. 20 and FIG. 21, some thickness of the bottom conductive layer 302 located in the second opening 402 is removed.

Referring to FIG. 22 and FIG. 23, a top conductive layer 303 filling the second opening 402 is formed. The remaining bottom conductive layer 302 and the top conductive layer 303 jointly constitute the capacitor contact structure 400.

In this embodiment, the top conductive layer 303 is made of a conductive material formed by Spin-On Deposition (SOD). The top conductive layer 303 formed by SOD has better adhesion and gap filling capability, which ensures that the top conductive layer 303 formed can completely fill the second opening 402.

The top conductive layer 303 may be made of one or more conductive materials, such as doped polysilicon, titanium, titanium nitride, tungsten and a tungsten compound. In this embodiment, the top conductive layer 303 is made of tungsten and a tungsten compound.

It is to be noted that, in other embodiments, prior to the formation of the top conductive layer, a contact layer may also be formed on a top surface of the bottom conductive layer. The contact layer is made of titanium nitride and is configured for an electrical connection between the bottom conductive layer formed by a conductive semiconductor material and the top conductive layer formed by a conductive metal material, so as to reduce resistance of an electrical connection path between the capacitor contact structure and the transistor in the substrate.

Compared with the related art, in the manufacturing process of forming the capacitor contact structure, some height of the virtual capacitor contact structure and some height of a virtual bitline structure are etched to form the first opening, and the insulation layer filling the first opening is formed, which prevents the problem of short circuit of conductors in a subsequently-formed capacitor contact pad caused by a deep void formed due to damages to part of the virtual capacitor contact structure during the formation of the capacitor contact structure.

Division of the steps above is only for ease of description, and during implementation, the steps may be combined into one step or some steps may be split into multiple steps, all of which shall fall within the protection scope of the patent provided that a same logical relationship is included. Insignificant modifications added to or insignificant designs introduced in a procedure without changing the core of the procedure shall fall within the protection scope of the patent.

A second embodiment of the present application relates to a semiconductor structure.

Referring to FIG. 1, FIG. 22 and FIG. 23, the semiconductor structure according to this embodiment is described in detail below with reference to the accompanying drawings. Contents the same or corresponding to those in the first embodiment are not described in detail below.

The semiconductor structure includes: a substrate 100 including a contact region 110 and a virtual region 120 arranged adjacent to each other; a bitline structure 102 and a dielectric layer 103, an extension direction of the dielectric layer 103 intersecting with that of the bitline structure 102, and the bitline structure 102 and the dielectric layer 103 defining discrete capacitor contact openings; a sacrificial layer 104 filling the capacitor contact opening in the virtual region 120, a height of a top surface of the sacrificial layer 104 being less than that of a top surface of the bitline structure 102; an insulation layer 105 filling the capacitor contact opening in the virtual region 120 and located on the top surface of the sacrificial layer 104, a height of a top surface of the insulation layer 105 being flush with that of the top surface of the bitline structure 102; and a capacitor contact structure 400 filling the capacitor contact opening in the contact region 110.

The substrate 100 includes a shallow trench isolation structure 140 and a wordline structure 150. The shallow trench isolation structure 140 is configured to isolate adjacent active regions (not shown). The wordline structure 150 is of a buried structure, is formed inside the substrate 100, acts as a gate of a transistor, and is configured to connect the bitline structure 102. It is to be noted that the substrate 100 further includes other semiconductor structures in addition to the shallow trench isolation structure 140 and the wordline structure 150. Since the other semiconductor structures do not involve the core technology of the present application, they are not described in detail herein. Those skilled in the art may understand that the substrate 100 further includes other semiconductor structures in addition to the shallow trench isolation structure 140 and the wordline structure 150, for the normal operation of the semiconductor structure.

The bitline structure 102 includes a bitline contact layer 112, a conductive contact layer 122, a metal layer 132 and a top dielectric layer 142 sequentially stacked. In this embodiment, the top dielectric layer 142 further covers sidewalls of the bitline contact layer 112, the conductive contact layer 122 and the metal layer 132 and acts as a first isolation layer of the bitline structure 102. A second isolation layer 152 is further formed on a sidewall of the first isolation layer. A third isolation layer 162 is further formed on a sidewall of the second isolation layer 152. In this embodiment, a structure of a plurality of isolation layers is formed on a sidewall of the bitline structure 102, so as to reduce parasitic capacitance between the bitline structure 102 and a capacitor contact structure formed by filling the capacitor contact opening.

In this embodiment, a difference between a height of a bottom surface of the insulation layer 105 and a height of the metal layer 132 in the bitline structure 102 is 20 nm to 90 nm. Parasitic capacitance between the metal layer of the bitline structure and other conductive structures is reduced by ensuring a distance between metal layer 132 in the bitline structure 102 and the bottom surface of a first opening 401.

In this embodiment, the capacitor contact structure 400 includes: a bottom conductive layer 302 located in the capacitor contact opening in the contact region 110, a height of a top surface of the bottom conductive layer 302 being less than that of the top surface of the bitline structure 102; and a top conductive layer 303 located on the top surface of the bottom conductive layer 302 and configured to fill the capacitor contact opening in the contact region 110.

It is to be noted that, in other embodiments, prior to the formation of the top conductive layer, a contact layer may also be formed on the top surface of the bottom conductive layer. The contact layer is made of titanium nitride and is configured for an electrical connection between the bottom conductive layer formed by a conductive semiconductor material and the top conductive layer formed by a conductive metal material, so as to reduce resistance of an electrical connection path between the capacitor contact structure and the transistor in the substrate.

Compared with the related art, the insulation layer filling the first opening in the virtual region, that is, the insulation layer located at a top of a virtual capacitor contact structure defined by a virtual bitline structure and the dielectric layer, prevents the problem of short circuit of conductors in a subsequently-formed capacitor contact pad caused by a deep void formed due to damages to part of the virtual capacitor contact structure during the formation of the capacitor contact structure.

Since the first embodiment is corresponding to this embodiment, this embodiment can collaborate with the first embodiment for implementation. Related technical details described in the first embodiment are still valid in this embodiment, and technical effects that can be achieved in the first embodiment may also be achieved in this embodiment, and are not described herein to avoid repetition. Correspondingly, related technical details described in this embodiment may also be applied to the first embodiment.

Those of ordinary skill in the art may understand that the above embodiments are specific embodiments for implementing the present application. However, in practical applications, various changes in forms and details may be made thereto without departing from the spirit and scope of the present application.

What is claimed is:

1. A semiconductor structure formation method, comprising:
providing a substrate, the substrate comprising a contact region and a virtual region arranged adjacent to each other, a bitline structure and a dielectric layer arranged discretely being formed on the substrate, an extension direction of the dielectric layer intersecting with that of the bitline structure, and the bitline structure and the dielectric layer defining discrete capacitor contact openings;
forming a sacrificial layer filling the capacitor contact opening;
removing, in the contact region, the sacrificial layer to form a second opening;
forming a bottom conductive layer filling the second opening;
removing, in the virtual region, some height of the sacrificial layer to form a first opening;
forming an insulation layer filling the first opening; and
forming a capacitor contact structure located in the second opening.

2. The semiconductor structure formation method according to claim 1, wherein the step of forming a sacrificial layer filling the capacitor contact opening comprises the following steps:
forming a sacrificial film filling the capacitor contact opening and covering the bitline structure and the dielectric layer; and
removing the sacrificial film higher than a top surface of the bitline structure to form the sacrificial layer.

3. The semiconductor structure formation method according to claim 1, wherein the step of removing, in the contact region, the sacrificial layer to form a second opening comprises the following steps:
forming, in the virtual region, a first mask layer located on top surfaces of the bitline structure, the dielectric layer and the sacrificial layer; and
removing, based on the first mask layer, the sacrificial layer in the contact region to form the second opening.

4. The semiconductor structure formation method according to claim 1, wherein the sacrificial layer in the contact region is removed by wet cleaning.

5. The semiconductor structure formation method according to claim 3, wherein the sacrificial layer in the contact region is removed by wet cleaning.

6. The semiconductor structure formation method according to claim 1, wherein the step of forming a bottom conductive layer filling the second opening comprises the following steps:
forming a conductive film filling the second opening and covering the virtual region; and
removing the conductive film higher than a top surface of the bitline structure to form the bottom conductive layer configured to fill the second opening.

7. The semiconductor structure formation method according to claim 1, wherein the step of removing, in the virtual region, some height of the sacrificial layer to form a first opening comprises the following steps:
forming, in the contact region, a second mask layer located on top surfaces of the bitline structure, the dielectric layer and the bottom conductive layer; and
removing, based on the second mask layer, some height of the sacrificial layer in the virtual region to form the first opening.

8. The semiconductor structure formation method according to claim 1, wherein some height of the sacrificial layer in the virtual region is removed by wet cleaning.

9. The semiconductor structure formation method according to claim 7, wherein some height of the sacrificial layer in the virtual region is removed by wet cleaning.

10. The semiconductor structure formation method according to claim 1, wherein in a direction perpendicular to the substrate, a distance between a metal layer located in the bitline structure and a bottom surface of the first opening formed is 20 nm to 90 nm.

11. The semiconductor structure formation method according to claim 1, wherein the step of forming an insulation layer filling the first opening comprises the following steps:
forming an insulation film filling the first opening and covering the contact region; and
etching the insulation film until top surfaces of the bitline structure and the dielectric layer are exposed in the contact region, so as to form the insulation layer.

12. The semiconductor structure formation method according to claim 1, wherein the step of forming a capacitor contact structure located in the second opening comprises the following steps:
removing some height of the bottom conductive layer located in the second opening; and
forming a top conductive layer filling the second opening, the remaining bottom conductive layer and the top conductive layer forming the capacitor contact structure.

13. A semiconductor structure, comprising:
a substrate comprising a contact region and a virtual region arranged adjacent to each other;
a bitline structure and a dielectric layer, an extension direction of the dielectric layer intersecting with that of the bitline structure, and the bitline structure and the dielectric layer defining discrete capacitor contact openings;
a sacrificial layer filling the capacitor contact opening in the virtual region, a height of a top surface of the sacrificial layer being less than that of a top surface of the bitline structure;
an insulation layer filling the capacitor contact opening in the virtual region and located on the top surface of the sacrificial layer, a height of a top surface of the insulation layer being flush with that of the top surface of the bitline structure; and
a capacitor contact structure filling the capacitor contact opening in the contact region.

14. The semiconductor structure according to claim 13, wherein the capacitor contact structure comprises:
a bottom conductive layer located in the capacitor contact opening in the contact region, a height of a top surface of the bottom conductive layer being less than that of the top surface of the bitline structure; and
a top conductive layer located on the top surface of the bottom conductive layer and configured to fill the capacitor contact opening in the contact region.

15. The semiconductor structure according to claim 13, wherein a difference between a height of a bottom surface of the insulation layer and a height of a metal layer in the bitline structure is 20 nm to 90 nm.
